(19) United States
(12) Patent Application Publication
(10) Pub. No.: US 2012/0058630 A1
(43) Pub. Date: Mar. 8, 2012

(54) Linear Cluster Deposition System

(75) Inventors: William E. Quinn, Whitehouse Station, NJ (US); Alexander Gurary, Bridgewater, NJ (US); Ajit Paranjpe, Basking Ridge, NJ (US); Maria D. Ferreira, Belle Mead, NJ (US); Roger P. Fremgen, JR., East Northport, NY (US); Eric A. Armour, Pennington, NJ (US)

(73) Assignee: Veeco Instruments Inc., Plainview, NY (US)

(21) Appl. No.: 12/877,775

(22) Filed: Sep. 8, 2010

(51) Int. Cl. H01L 21/36; C23C 16/06; C23C 16/08; C23C 16/00; C23C 16/44

(52) U.S. Cl. 438/483; 118/719; 427/255.28; 427/255.39; 438/478; 257/E21.461

(57) ABSTRACT

A linear cluster deposition system includes a plurality of reaction chambers positioned in a linear horizontal arrangement. First and second reactant gas manifolds are coupled to respective process gas input port of each of the reaction chambers. An exhaust gas manifold having a plurality of exhaust gas inputs is coupled to the exhaust gas output port of each of the plurality of reaction chambers. A substrate transport vehicle transports at least one of a substrate and a substrate carrier that supports at least one substrate into and out of substrate transfer ports of each of the reaction chambers. At least one of a flow rate of process gas into the process gas input port of each of the reaction chambers and a pressure in each of the reaction chambers being chosen so that process conditions are substantially the same in at least two of the reaction chambers.

The section headings used herein are for organizational purposes only and should not to be construed as limiting the subject matter described in the present application in any way.

### Introduction

Many electronic and optical devices are fabricated using multi-chamber processing systems known as cluster tools. These cluster tools typically process substrates in a sequential manner. Cluster tools typically include a frame that houses at least one substrate transfer robot which transports substrates between a pod/cassette mounting device and multiple processing chambers that are connected to the frame. For example, cluster tools are commonly used for track photolithography.

Cluster tools can also be used for chemical vapor deposition (CVD) including reactive gas processing. Chemical vapor deposition involves directing one or more gases containing chemical species onto a surface of a substrate so that the reactive species react and form a film on the surface of the substrate. For example, CVD can be used to grow compound semiconductor material on a crystalline semiconductor substrate. Compound semiconductors, such as III-V semiconductors, are commonly formed by growing various layers of semiconductor materials on a substrate using a source of a Group III metal and a source of a Group V element. In one CVD process, sometimes referred to as a chloride process, the Group III metal is provided as a volatile halide of the metal, which is most commonly a chloride, such as GaCl₃, and the Group V element is provided as a hydride of the Group V element.

One type of CVD is known as metal organic chemical vapor deposition (MOCVD), which is sometimes called organometallic vapor-phase epitaxy (OMVPE). MOCVD uses chemical species that include one or more metal-organic compounds, such as alkyls of the Group III metals, such as gallium, indium, and aluminum. MOCVD also uses chemical species that include hydrides of one or more of the Group V elements, such as NH₃, AsH₃, PH₃ and hydrides of antimony. In these processes, the gases are reacted with one another at the surface of a substrate, such as a substrate of sapphire, Si, GaAs, InP, InAs or GaP, to form a III-V compound of the general formula In_{X}Ga_{Y}Al_{Z}N_{A}As_{B}P_{C}Sb_{D}, where X+Y+Z equals approximately one, and A+B+C+D equals approximately one, and each of X, Y, Z, A, B, and C can be between zero and one. In some instances, bismuth may be used in place of some or all of the other Group III metals.

Another type of CVD is known as Halide Vapor Phase Epitaxy (HVPE). In one important HVPE process, Group III nitrides (e.g., GaN, AlN, and AlGaN) are formed by reacting hot gaseous metal chlorides (e.g., GaCl₃ or AlCl₃) with ammonia gas (NH₃). The metal chlorides are generated by passing hot HCl gas over the hot Group III metals. All reactions are done in a temperature controlled quartz furnace. One feature of HVPE is that it can have a very high growth rate, that is up to or greater than 100 μm per hour for some state-of-the-art processes. Another feature of HVPE is that it can be used to deposit relatively high quality films because films are grown in a carbon-free environment and because the hot HCl gas provides a self-cleaning effect.

Another type of CVD is known as Halide Vapor Phase Epitaxy (also known as HVPE). HVPE processes are used to deposit Group III nitrides (e.g., GaN, AlN, AlN, and AlGaN) and other semiconductors (e.g. GaAs, InP and their related compounds). These materials are formed with Group III elements arranged as metals and supplied to a substrate through hydrogen halide. Materials are formed by reacting hot gaseous metal chlorides (e.g., GaCl or AlCl) with ammonia gas (NH₃) or hydrogen. The metal chlorides are generated by passing hot HCl gas over the hot Group III metals. One feature of HVPE is that very high growth rate can be achieved.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale, emphasis instead generally being placed upon illustrating principles of the teaching. The drawings are not intended to limit the scope of the Applicants' teaching in any way.

FIG. 1 illustrates a perspective view of a linear cluster deposition system according to the present teaching.

FIG. 2A illustrates five linear cluster deposition systems according to the present teaching positioned in a horizontal arrangement.

FIG. 2B illustrates ten linear cluster deposition system according to the present teaching positioned in a horizontal arrangement.

FIG. 3 illustrates a perspective view of the processing area of a linear cluster deposition system according to the present teaching.

FIG. 4A illustrates a cross-sectional end-view of a linear cluster deposition system according to the present teaching showing reaction chambers positioned on both sides of a common area.

FIG. 4B illustrates a cross-sectional side-view of a linear cluster deposition system according to the present teaching showing a first and second source gas manifold and the exhaust gas manifold coupled to the plurality of reaction chambers.

### DESCRIPTION OF VARIOUS EMBODIMENTS

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the methods of the present teachings may be performed in any order and/or simultaneously as long as the teaching remains operable. Furthermore, it should be understood that the apparatus and methods of the present teachings can include any number or all of the described embodiments as long as the teaching remains operable.

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

The present teaching relates to methods and apparatus for batch reactive gas phase processing, such as CVD, MOCVD, and HVPE (both hydride and halide vapor phase epitaxy). In most known batch reactive gas phase processing systems, a plurality of semiconductor substrates are mounted in a substrate carrier inside a batch reaction chamber. The most common type of batch reactive gas phase processing reactor is a rotating disc reactor that supports a plurality of substrates for processing. Such a reactor typically uses a disc-like substrate carrier. The substrate carrier has pockets or other features arranged to hold the plurality of substrates. The carrier, with the substrates positioned thereon, is placed into a reaction chamber and held with the substrate-bearing surface of the carrier facing in an upstream direction. The carrier is rotated during deposition, typically at rotational velocities that are in the range of 50 rpm to 1,500 rpm, about an axis extending in the upstream to downstream direction. The rotation of the substrate carrier improves uniformity of the deposited material. The substrate carrier is maintained at a desired elevated temperature, which can be in the range of about 350° C. to about 1,600° C. during this process.

A gas distribution injector or injector head is mounted facing towards the substrate carrier. The injector or injector head typically includes a plurality of gas inlets that receive a combination of process gases. The gas distribution injector typically directs the combination of gases from gas input ports of the injector to certain targeted regions of the reaction chamber where the plurality of substrates are positioned. Many gas distribution injectors have showerhead devices spaced in a pattern on the head. The gas distribution injectors direct the precursor gases at the substrate carrier in such a way that the precursor gases react as close to the substrates as possible, thus maximizing reaction processes and epitaxial growth at the substrate surface. Some gas distribution injectors provide a shroud that assists in providing a laminar gas flow during the chemical vapor deposition process. One or more carrier gases can be used to assist in providing a laminar gas flow during the chemical vapor deposition process. The carrier gas typically does not react with any of the process gases and does not otherwise affect the chemical vapor deposition process.

In operation, the substrate carrier is rotated about the axis, the reaction gases are introduced into the chamber from a flow inlet element above the substrate carrier. The flowing gases pass downwardly toward the carrier and substrates, preferably in a laminar plug flow. As the gases approach the rotating carrier, viscous drag impels them into rotation around the axis so that in a boundary region near the surface of the carrier, the gases flow around the axis and outwardly toward the periphery of the carrier. As the gases flow over the outer edge of the carrier, they flow downwardly toward exhaust ports positioned below the carrier. Most commonly, CVD processes are performed with a succession of different gas compositions and, in some cases, different substrate temperatures, to deposit a plurality of layers of semiconductor having differing compositions as required to form a desired semiconductor device.

For example, in MOCVD processes, the injector introduces combinations of precursor gases including metal organics, hydrides, and halides, such as ammonia or arsine into a reaction chamber through the injector. Carrier gases, such as hydrogen, nitrogen, or inert gases, such as argon or helium, are often introduced into the reactor through the injector to aid in maintaining laminar flow at the substrate carrier. The precursor gases mix in the reaction chamber and react to form a film on a substrate. Many compound semiconductors, such as GaAs, GaN, GaAlAs, InGaAsSb, InP, ZnSe, ZnTe, HgCdTe, InAsSbP, InGaN, AlGaN, SiGe, SiC, ZnO and InGaAlP, have been grown by MOCVD.

In both MOCVD and HVPE (both hydride and halide vapor phase epitaxy) processes, the substrate is maintained at an elevated temperature within a reaction chamber. In some processes, the process gases are maintained at a relatively low temperature of about 50-60° C. or below, when they are introduced into the reaction chamber. As the gases reach the hot substrate, their temperature, and hence their available energy for reaction, increases. In other processes, the process gasses are heated to a relatively high temperature, which is below the cracking temperature of the hydride gases, and are then introduced into the reaction chamber. For example, the process gasses can be heated to about 200° C. In these processes, the reaction chamber wall is maintained at a relatively cold or warm temperature, rather than a hot temperature. In some processes, different gases are pre-heated to different temperatures.

Batch or parallel processing is commonly used to increase substrate throughput in semiconductor processing equipment. In batch and parallel processing systems, multiple substrates are processed at the same time in a batch reaction chamber. Batch and parallel processing, however, has some inherent disadvantages. For example, in batch processing systems, cross contamination of substrates is common. Also, batch processing can inhibit process control and process repeatability from substrate-to-substrate and from batch-to-batch. Consequently, batch processing can severely affect overall system maintenance, yield, reliability, and therefore net throughput and productivity. Batch processing is typically inefficient from floorspace and gas usage considerations for processing substrates with large diameters due the poor packing efficiency of large diameter substrates on a carrier. For substrate diameters above a certain size, batch processing systems become too large and unwieldy to manufacture and maintain.

One aspect of the cluster deposition system of the present teaching is that a plurality of separate reactors are used to process a single substrate or a small number of substrates in contrast to processing a relatively large number of substrates in a single batch processing reactor. One advantage of using a plurality of separate relatively small reactors, where each of the plurality of reactors processes a single substrate or a small number of substrates, is that more uniform and more controllable thermal and gas flow patterns can be achieved in these smaller reactors. These more uniform patterns results in the realization of higher process yields without the process control and process substrate-to-substrate and batch-to-batch repeatability problems associated with conventional batch processing in a single relatively large reaction chamber. Smaller chambers may also reduce process overhead for each run because faster temperature ramp up/down, shorter gas flow stabilization, and shorter post process pump-down can be achieved which further improves productivity.

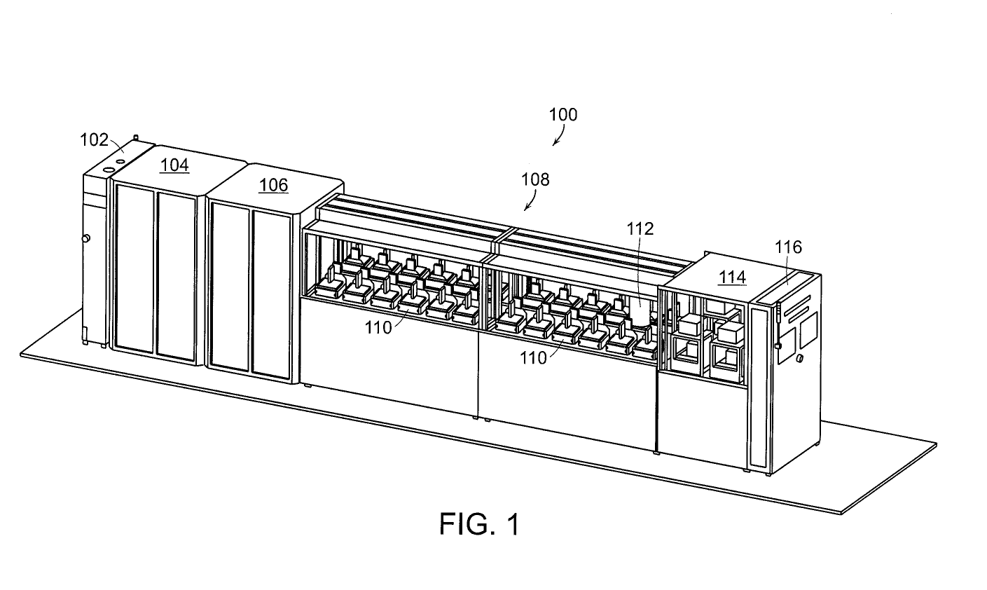

FIG. 1 illustrates a perspective view of a linear cluster deposition system 100 according to the present teaching. The deposition system 100 includes an electrical panel 102 that supplies power to the system and that includes circuit breakers and other control devices. One aspect of the cluster deposition system of the present teaching is that the reaction chambers can share common power supplies. The cluster deposition system of the present teaching is scalable to a large number of reaction chambers. Each of the plurality of reaction chambers can be powered by common power supplies. In addition, common power supplies can be used to power the various sensors and controllers, such as pressure and temperature sensors and the mass flow controllers.

The deposition system 100 also includes common vacuum pumps 104 and filters that are coupled to the plurality of reaction chambers. The vacuum pumps control the pressure inside the plurality of process chambers and also remove purge, process, and carrier gasses from the plurality of reaction chambers. Numerous types of vacuum pumps can be used such as turbomolecular vacuum pumps. One aspect of the cluster deposition system of the present teaching is that a common exhaust gas manifold can be used. Using a common exhaust gas manifold saves valuable space and significantly reduces the cost of the exhaust gas system.

The deposition system 100 also includes a source gas manifold 106. The source gas manifold 106 can include a source gas cabinet that contains the physical source gas bottles. Alternatively, the source gas bottles can be remotely located in a centralized gas facility and the source gasses can be provided to the source gas manifold 106 with gas tubing. One aspect of the cluster deposition system of the present teaching is that common reactant source gas and carrier gas manifolds can be used for each of the plurality of reaction chambers. Using common reactant source and carrier gas manifolds save valuable space and significantly reduce the cost of the process gas systems. In addition, fewer source ampoules are required to service multiple reactors. Therefore, the overhead associated with replenishment of source ampoules is reduced.

The deposition system 100 includes a processing area 108 with a plurality of reaction chambers 110 that is configured in a horizontal in-line or linear configuration. Each of the plurality of reaction chambers 110 has at least one process gas input port, an exhaust gas output port, and a substrate transfer port. The plurality of reaction chambers 110 can include separate gas input ports for each of the reactant gasses for chemical vapor deposition. In some embodiments, each of the plurality of reaction chambers 110 has substantially the same dimensions so that process conditions can be more easily matched for all of the plurality of reaction chambers 110. In some embodiments, each of the plurality of reaction chambers 110 is dimensioned to process a single substrate or a substrate carrier that supports a single substrate. In other embodiments, at least one of the plurality of reaction chambers 110 is dimensioned to process a small number of substrates or a substrate carrier that supports a small number of substrates. In one specific embodiment, the substrates are 200-300 mm in diameter.

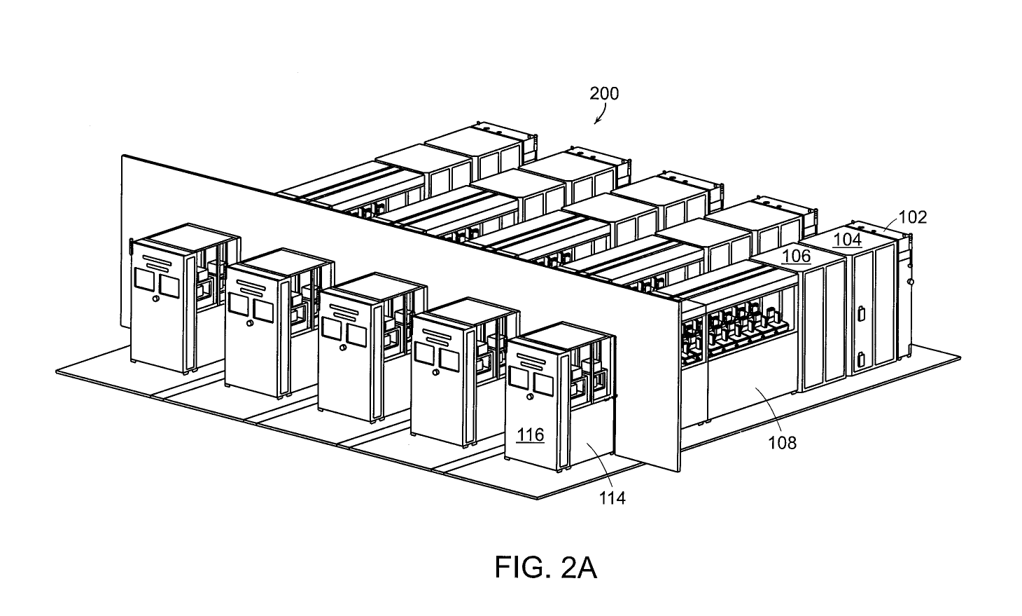

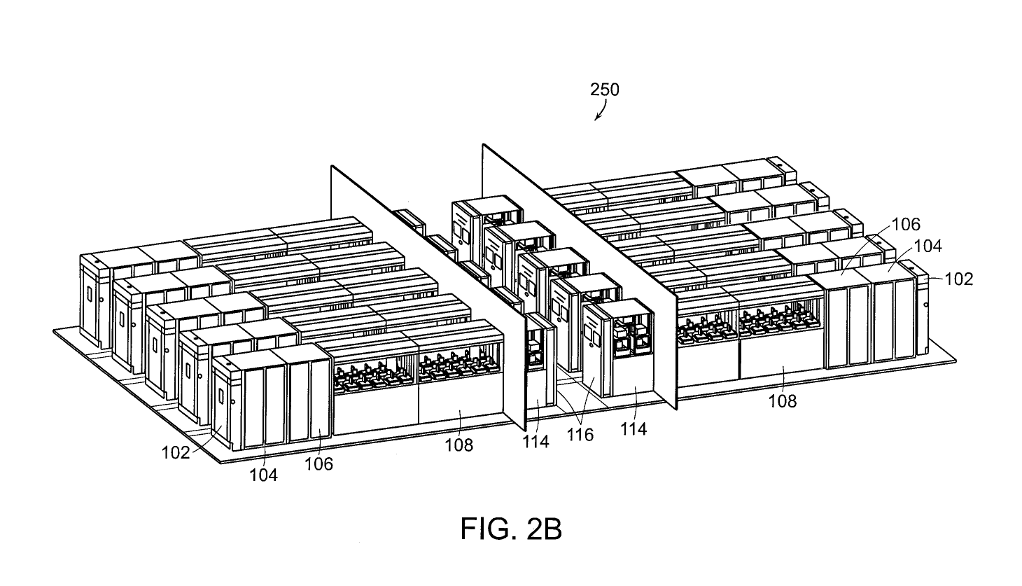

The deposition system 100 is scalable to a very large number of reaction chambers. If fact, the deposition system 100 is scalable to an almost unlimited number of reaction chambers that is much larger than the number of reaction chambers that can be configured in conventional non-linear cluster deposition systems, such as circular cluster tools. The deposition system 100 can also include a plurality of linear cluster deposition systems according to the present teaching that are positioned adjacent to each other (horizontally or vertically) in various configurations as shown in FIGS. 2A and 2B. The plurality of linear cluster deposition systems can include at least some common system components such as control systems, process gas supplies, exhaust gas manifolds, and substrate handling systems.

The area under the plurality of reaction chambers 110 includes plumbing for the source gas and exhaust gas manifolds. This area includes space for mass flow controllers. In addition, this area includes space for pressure controllers to regulate the pressure in the plurality of reaction chambers 110.

The deposition system 100 includes a substrate transport vehicle 112 that transports either a substrate or a substrate carrier that supports at least one substrate into and out of the substrate transfer ports of each of the plurality of reaction chambers 110. Numerous types of substrate transport vehicles can be used. For example, there are numerous types of robotic substrate transport vehicles known in the art. In the embodiment shown, the substrate transport vehicle 112 is a robotic arm that moves in a linear direction along a rail system in the purge space outside of the plurality of reaction chambers 110. One aspect of the cluster deposition system of the present teaching is that a common substrate transport vehicle 112 can be used to move substrates and substrate carriers into and out of the plurality of reaction chambers 110. The common substrate transport vehicle 112 can also be used to move substrates and substrate carriers into cleaning chambers and from the cleaning chambers to the plurality of reaction chambers 112 in the cluster deposition system.

In addition, the plurality of reaction chambers 110 can share a common substrate cassette loading and unloading module 114 where substrates can be stored prior to deposition and after deposition and before removal from the cluster deposition system 100. The substrate cassette loading/unloading module 114 can store the cassettes in a reduced pressure or in an inert atmosphere for cooling before unloading the substrates.

The deposition system also includes a system control module 116 that includes controls for operating the system. For example, the system control module 116 can include a controller for operating the substrate transport vehicle 112, the mass flow controllers, gas valves at the source gasses, pressure control valves in the plurality of reaction chambers 110, and the substrate transfer port in each of the plurality of reaction chambers 110. One aspect of the cluster deposition system of the present teaching is that some or all of the plurality of reaction chambers 110 can share common power supplies and control units. The cluster deposition system of the present teaching is scalable to a large number of reaction chambers. Each of the plurality of reaction chambers 110 can be controlled with a single control module. In addition, common power supplies can be used to power the various sensors and controllers, such as pressure and temperature sensors and the mass flow controllers.

FIG. 2A illustrates five linear cluster deposition systems 200 according to the present teaching positioned in a horizontal arrangement. FIG. 2B illustrates ten linear cluster deposition systems 250 according to the present teaching positioned in a horizontal arrangement. The substrate cassette loading/unloading module 114 and the system control module 116 are typically located in a clean room environment. FIGS. 2A and 2B illustrate that very little clean room space is required for batch processing a large number of substrates. The processing area 108, source gas manifold 106, vacuum pumps 104, and electrical panel 102 are typically located outside of the clean room in a service or utility room. However, one skilled in the art will appreciate that many different configurations are possible.

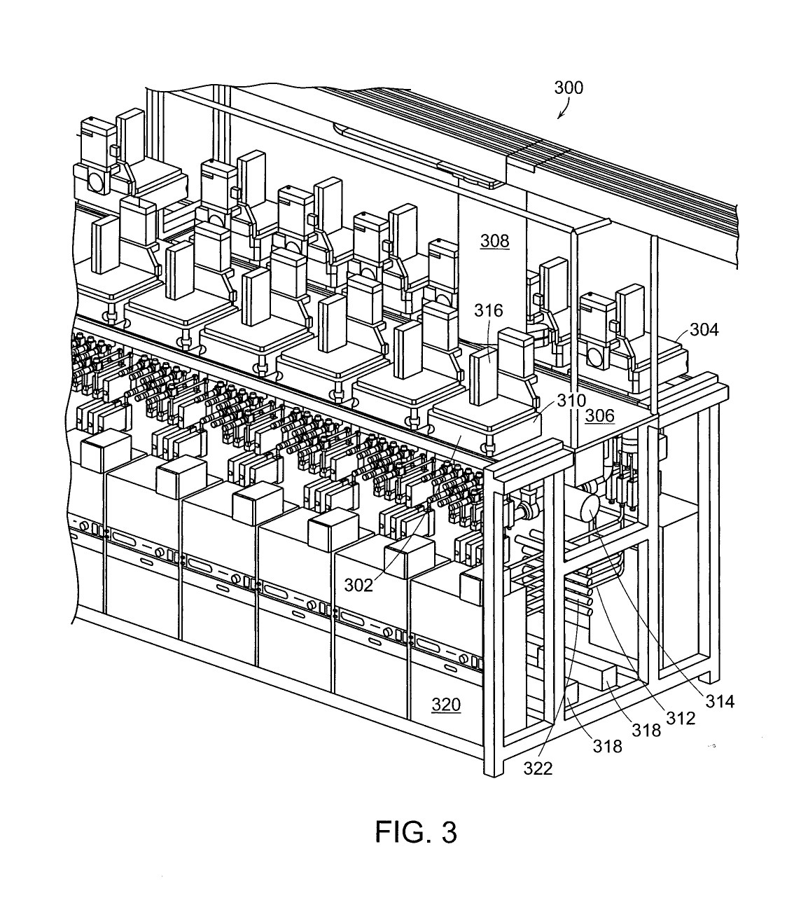

FIG. 3 illustrates a perspective view of the processing area 300 (shown in FIGS. 1, 2A and 2B as processing area 108) of a linear cluster deposition system according to the present teaching. The processing area 300 includes a first 302 and second plurality of chambers 304 and a common area 306 between the first 302 and second plurality of chambers 304 that has a controlled environment which is typically an inert gas environment. The common area 306 can be under vacuum conditions. The common area 306 provides a space for the substrate transport vehicle to move substrates and/or substrate carrier into and out of the various chambers.

Each of the first plurality of chambers 302 is a group of reaction chambers or reactors that process a single substrate or a small number of substrates. Each of the plurality of reaction chamber 302 includes a substrate transfer port 310, such as a gate valve or a pneumatically operated sealed door that provides a vacuum seal. The substrate transfer port 310 does not need to provide a high vacuum seal for many applications. A pressure sensor can be positioned inside each of the plurality of reaction chambers 302 to measure the pressure of reactant gasses. An exhaust throttle valve can be positioned in each of the plurality of reaction chambers 302 to control the pressure of the reactant gasses inside the reaction chamber 302. A control input of the exhaust throttle valve is electrically connected to an output of a processor in the system control module 116 (FIG. 1). The processor generates a control signal that adjusts the position of the exhaust gas valve in order to achieve a desired chamber pressure in the associated reaction chamber 302.

Each of the second plurality of chambers 304 can also be a reaction chamber. However, in some embodiments, some or all of the chambers in the second plurality of chambers 304 are cleaning chambers. Numerous types of cleaning chambers can be used. The cleaning chambers can be used to clean only the substrates, only the substrate carriers, or both the substrates and the substrate carriers. For example, the cleaning chambers can be vacuum bake furnaces that heat the substrates or the substrate carriers to a high temperature to bake off impurities. For example, the vacuum bake furnaces can heat the substrates to a temperature that is on order of about 1350-1400 degrees Celsius in a reduced atmosphere, such as an atmosphere that is less than about 10 Ton. The cleaning chamber can also be configured to provide a halide gas, such as chlorine gas, for cleaning prior to deposition. The cleaning chamber can also be configured to provide an HCL gas environment for cleaning prior to deposition.

The substrate transport vehicle shown in FIG. 3 is a linear robot 308. The linear robot 308 moves substrates and/or substrate carrier into and out of the various reactors and cleaning chambers. The linear robot 308 can include various means for engaging the substrates and/or substrate carriers. For example, the linear robot 308 can include a Venturi end-effector that transports substrates into and out of the first 302 and second plurality of chambers 304 without physical contact. The linear robot 308 can also include a fork-shaped end-effector that is designed to pick up and transport substrate carriers into and out of the first 302 and second plurality of chambers 304.

Common reactant gas manifolds 312 are positioned under the common area 306. The reactant gas manifolds 312 include a plurality of gas lines for process gasses and cleaning gasses, such as H₂, N₂, HCl, NH₃, and metal organics gasses. In many embodiments, there is at least a first and second reactant gas line for providing at least two different reactant gasses to the plurality of reaction chambers 302. Each of the first and second reactant gas manifolds 312 have a plurality of process gas outputs, a respective one the plurality of process gas outputs of each of the first and second reactant gas manifold is coupled to a respective process gas input port of each of the plurality of reaction chambers 302. The plurality of reaction chambers 302 can have a single process gas input port or can have multiple process gas input ports. For example, the plurality of reaction chambers 302 can have a separate process gas input port for each of the reactive gasses to prevent any reaction from occurring outside of the reaction chamber 302.

A common exhaust gas manifold 314 is positioned under the common area 306. The common exhaust gas manifold 314 has a plurality of exhaust gas inputs, a respective exhaust gas input being coupled to a respective exhaust gas output port of the plurality of reaction chambers 302. The output of the exhaust gas manifold 314 is coupled to the common vacuum pumps 104 (FIG. 1).

Various sensors can be positioned in the processing area 300 or in the plurality of reaction chambers 302 to monitor deposition in-situ. For example, a pyrometer can be positioned proximate to some or all of the plurality of reaction chambers 302 to monitor the process temperature. Also, a deposition monitor 316 can be positioned proximate to or inside some or all of the plurality of reaction chambers 302 to monitor the deposited film properties. The deposition monitor 316 determines various film properties, such as film growth rate, film thickness, film composition, film stress, film density, and optical transmission. Various types of deposition monitors can be used to measure various metrology parameters. For example, various deposition monitor can be used to measure photoluminescence, white light reflectance, reflectometry, and scatterometry.

Outputs of the various sensors are electrically connected to a processor in the system control module 116 (FIG. 1). In many embodiments, the processor receives the data from the sensors and generates control signals for various components, such as throttle valves and mass flow controllers that achieve substantially the same deposition conditions in all of the plurality of reaction chambers 302.

For example, a deposition rate monitor, such as a reflectometer, ellipsometer, or quartz crystal monitor, can be used to measure the film growth rate in each of the plurality of reaction chambers. The deposition rate monitor can be used in a feedback loop to modulate the reactant gas flow rate so that the deposition rate in each reaction chamber is the same. The advantage to this feedback system is that gas mixing components can be shared among the reaction chambers, thus reducing system component costs.

Various utilities are located underneath the first 302 and second plurality of chambers 304 and the common area 306. For example, an electrical power grid 318 can be located underneath the common area 306 to provide power directly to the system components and/or to separate power supplies 320 that are used to power system components. In addition, cooling water lines 322 for the plurality of reaction chambers 302 are located underneath the common area 306.

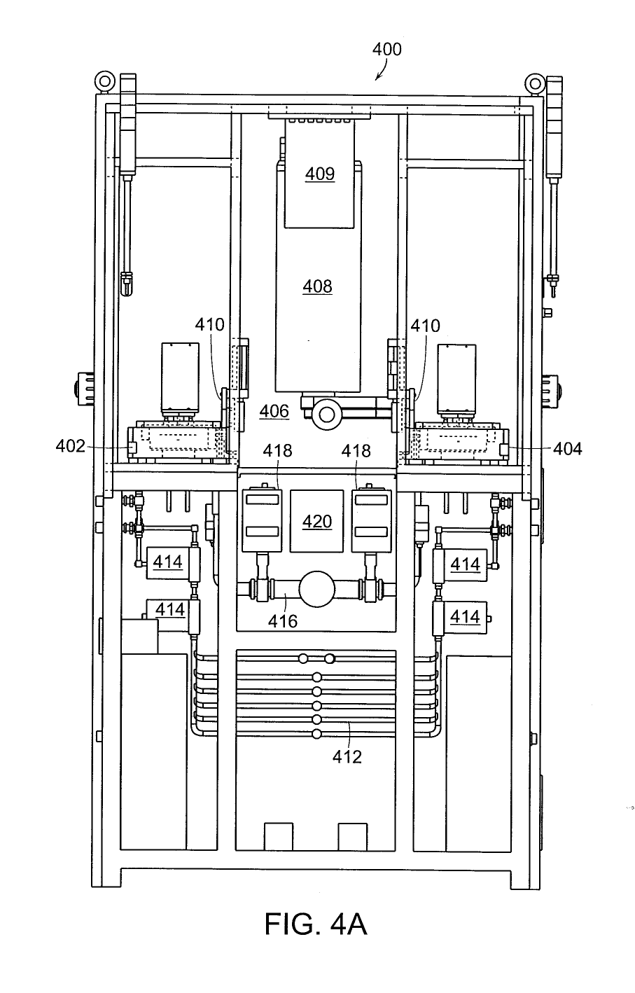

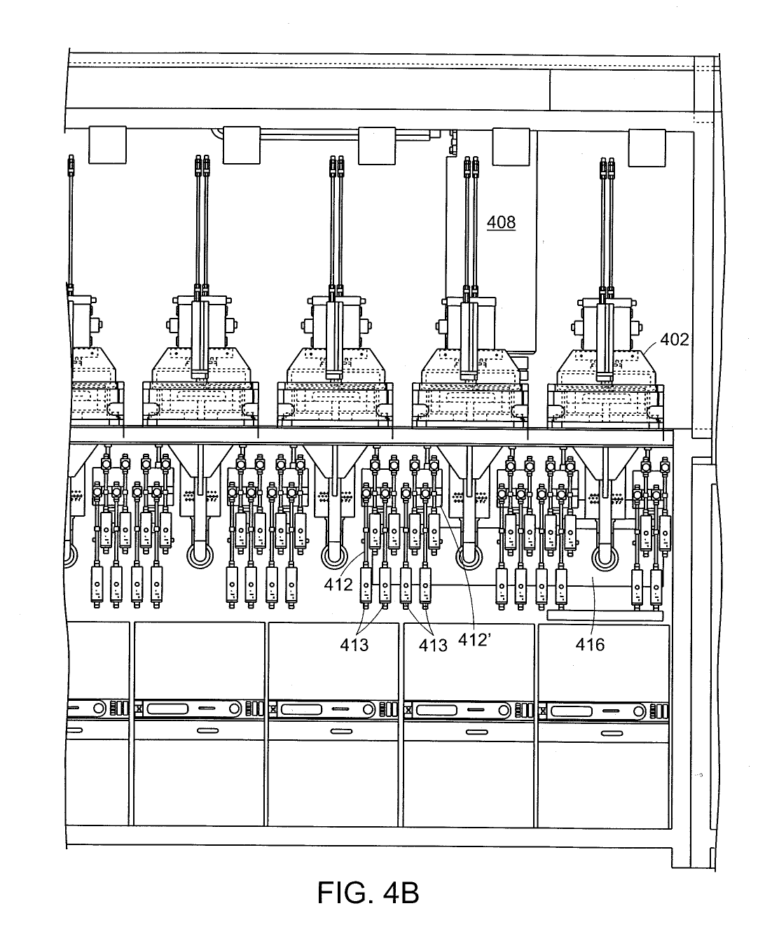

FIG. 4A illustrates a cross-sectional end-view of a linear cluster deposition system 400 according to the present teaching showing reaction chambers 402, 404 positioned on both sides of a common area 406. The substrate transport vehicle is shown as a robotic arm 408 mounted on a rail or track 409 system that allows the robotic arm 408 to move down the entire length of the system so that substrates can be transferred in and out of each of the first and second plurality of chambers 302, 304 (FIG. 3). The robotic arm 408 is located in the common area 406, which has a protective environment, such as an inert gas environment.

The substrate transfer port is shown as a gate valve 410 at the end of the reaction chambers 402, 404 that is adjacent to the common area. The gate valve 410 opens to allow substrates to be positioned into the reaction chamber 402, 404 for deposition and removed from the reaction chambers 402, 404 after deposition.

The source gas manifold 412 is shown as gas lines extending through the length of the deposition system 400 and then branching horizontally across the width of the deposition system 400 and then vertically into mass flow controllers 414 for each of the reaction chambers 402, 404. The outputs of the mass flow controllers 414 are coupled into the process gas input ports of the reaction chambers 402, 404.

The exhaust gas manifold 416 is shown as an exhaust line with a relatively high conductance, which extends through the length of the deposition system 400 and then branches horizontally across the width of the system 400 and then vertically into the exhaust gas output ports of the reaction chambers 402, 404. Separate vacuum pumps 418 can be positioned in the vacuum line connecting to the exhaust gas output port of each of the reaction chambers 402, 404. A ventilation channel 420 is shown between the vacuum pumps to provide fresh air to the system. Filters may also be placed in the vacuum lines connected to the reaction chambers 402, 404.

FIG. 4B illustrates a cross-sectional side-view of a linear cluster deposition system 400 according to the present teaching showing a first and second source gas manifold 412, 412′ and the exhaust gas manifold 416 coupled to the plurality of reaction chambers 402. The first and second source gas manifold 412, 412′ typically provide two different reactant gases to the reaction chamber 402. A mass flow controller 413 is coupled into each of the gas lines in the source gas manifolds 412, 412′. The exhaust gas manifold 416 is coupled to an exhaust gas output port of each of the plurality of reaction chambers 402.

One aspect of the present teaching is a method of simultaneous depositing material in a deposition system with a plurality of reaction chambers. The method can be used for numerous types of deposition processes. For example, the method can be used for depositing material using chemical vapor deposition, organometallic vapor-phase epitaxy, halide vapor phase epitaxy, and hydride vapor phase epitaxy. The method can be used to deposit both compound semiconductor materials and elemental semiconductor materials.

Referring to FIGS. 1, 3, and 4, a method of the present teaching includes providing a plurality of reaction chambers 302 positioned in a linear horizontal arrangement. A substrate or a substrate carrier that supports at least one substrate is transported into each of the plurality of reaction chambers 302 for simultaneous deposition. In some methods, the substrates or the substrate carriers that support the at least one substrate are transported into a cleaning chamber for cleaning in at least one of a high temperature and a halide gas environment prior to simultaneous deposition. The substrates can be transported into the plurality of reaction chambers 302 and cleaning chambers without physical contact.

Reactant gas is provided from at least two common reactant gas manifolds into each of the plurality of reaction chambers 302. The reactant gas and reaction products are exhausted from the plurality of reaction chambers 302 into a common exhaust gas manifold. At least one of process parameters and reaction chamber parameters are adjusted so that process conditions are substantially the same in each of the plurality of reaction chambers 302. The substrate or the substrate carrier that supports at least one substrate is then transported out of each of the plurality of reaction chambers 302 after the simultaneous deposition. The substrates can be transported without physical contact.

In many methods according to the present teaching, the process parameters in each of the plurality of reaction chambers 302 are matched. For example, process parameters, such as the chamber pressure, reactant and carrier gas flow rates, and the temperature in the plurality of reaction chambers 302 can be matched in all or at least some of the plurality of reaction chambers 302. Chamber pressure matching can be accomplished by matching the pumping speed of the vacuum pumps evacuating the reactant gases and by-products from the plurality of reaction chambers 302. The flow rates of the reactant and carrier gases in each of the plurality of reaction chambers 302 can be matched by matching the operational parameters of the mass flow controllers and by matching the gas delivery line pressures.

Also, in many methods according to the present teaching, the reaction chamber parameters in each of the plurality of reaction chambers 302 are matched. Linear cluster deposition systems according to the present teaching can be built with adjustable components that can be modified to match the process conditions in each of the plurality of chambers 302. For example, components such as reactant gas injectors can have adjustable nozzles to compensate for small differences in conductance and chamber volume between reaction chambers. Also, the position, type, and size of heating filaments in the plurality of chambers 302 can be adjusted to change the thermal profile in each of the plurality of reaction chambers 302. Also, the position of the spindle attached to the platen supporting the substrates or the substrate carrier can be adjusted to change the reactant and carrier gas flow patterns.

Feedback from various sensors and instruments can be used to adjust process parameters and/or reaction chamber parameters to more closely match the process conditions in each of the plurality of reaction chambers. Process conditions in some or all of the plurality of chambers can be matched to achieve various process and/or system goals. For example, process conditions can be matched to match the thickness of films deposited in some or all of the plurality of chambers. Also, process conditions can be matched to match the alloy composition of films deposited in some or all of the plurality of chambers. In addition, process conditions can be matched to match the doping levels of films deposited in some or all of the plurality of chambers. One skilled in the art will appreciate that process conditions can be matched to match numerous other process and/or system goals.

Furthermore, process conditions can be chosen and matched in some or all of the plurality of chambers to achieve within-wafer uniformity of various process parameters, such as film thickness, film composition, and/or doping level. Also, the process and/or systems goals can be achieved individually or simultaneously. That is, process conditions in some or all of the plurality of chambers can be matched to achieve one or more of the process parameters.

For example, each of the plurality of reaction chambers 302 typically includes chamber pressure and chamber temperature sensors. Also, some or all of the plurality of reaction chambers 302 can include deposition growth rate sensors that measure the deposited film thickness. In addition, some or all of the plurality of reaction chambers 302 can include various metrology instruments that determine various metrology parameters, such as photoluminescence, electroluminescence, morphology, and carrier emissivity, used for determining numerous film properties. Any analog data from these sensors and instruments is transmitted to analog-to-digital converts that convert the analog data to digital signals.

The digital signals and other digital data are transmitted to a processor or multiple processors that use algorithms, calibration tables, and/or system models to determined control signals for various system and reaction chamber components that adjust process parameters to more closely match process conditions in the plurality of reaction chambers 302. For example, the digital signals and other digital data can be used to adjust chamber temperature, reactant and carrier gas flow rate, and chamber pressure. The calibration tables and system models are useful in practical systems where there are small physical manufacturing differences in the plurality reaction chambers 302 and other system components and where process parameters cannot be precisely controlled. For example, software, such as Rudolph Artist, which is commercially available from Rudolph Technologies, can be used. In various embodiments, process and chamber parameters can be adjusted during or in between process runs.

There are numerous other methods for ensuring chamber matching. For example, one such method is subjecting a reference carrier to a known thermal process and comparing the resulting thermal fingerprint of each chamber to a known baseline in order to permit rapid detection of thermal excursions. Similarly, the gas delivery and vacuum instrumentation could be connected sequentially in an automated fashion either to an on-board or to an off-line instrumentation system for rapid real-time calibration and monitoring of such devices. These and other methods that have commonly been used for chamber matching can be adapted to the multi-chamber architecture described herein. Such calibrations would typically be performed between runs to correct for chamber drift and to ensure continual chamber matching.

The methods and apparatus described herein are useful for synchronized parallel processing of wafers in multiple chambers. However, one skilled in the art will appreciate that that methods and apparatus of the present teaching can use complete or partial asynchronous operation in which gas flows are directed in turn to each chamber. Only slight modifications to the gas delivery system are needed to change the mode of operation of the apparatus described herein. For example, different processes may be performed in different chambers, such as processing a part of the layer stack in one set of chambers and completing the layer stack in another set of chambers. Also, one set of chambers could be used for processing one layer stack and another set of chambers could be used for processing a different layer stack.

In addition, in many methods according to the present teaching, the process sequence of transporting substrates into and out of the reaction chambers 302 and cleaning chambers 304 (in some embodiments) is synchronized using the central control system 116 (FIG. 1).

### EQUIVALENTS

While the Applicants' teaching are described in conjunction with various embodiments, it is not intended that the Applicants' teaching be limited to such embodiments. On the contrary, the Applicants' teaching encompass various alternatives, modifications, and equivalents, as will be appreciated by those of skill in the art, which may be made therein without departing from the spirit and scope of the teaching.

What is claimed is:

1. A linear cluster deposition system comprising:
a) a plurality of reaction chambers positioned in a linear horizontal arrangement, each of the plurality of reaction chambers having a process gas input port, an exhaust gas output port, and a substrate transfer port;
b) a first and second reactant gas manifold each of the first and second reactant gas manifold having a plurality of process gas outputs, a respective one the plurality of process gas outputs of each of the first and second reactant gas manifold being coupled to a respective process gas input port of each of the plurality of reaction chambers;
c) an exhaust gas manifold having a plurality of exhaust gas inputs, a respective exhaust gas input being coupled to a respective exhaust gas output port of the plurality of reaction chambers; and
d) a substrate transport vehicle that transports at least one of a substrate and a substrate carrier that supports at least one substrate into and out of the substrate transfer ports of each of the plurality of reaction chambers,
wherein at least one process parameter is chosen so that process conditions are substantially the same in at least two of the plurality of reaction chambers.

2. The linear cluster deposition system of claim 1 wherein the process conditions are chosen for organometallic vapor-phase epitaxy.

3. The linear cluster deposition system of claim 1 wherein the process conditions are chosen for halide vapor phase epitaxy.

4. The linear cluster deposition system of claim 1 wherein the process conditions are chosen for chemical vapor deposition.

5. The linear cluster deposition system of claim 1 wherein the process conditions are chosen for hydride vapor phase epitaxy.

6. The linear cluster deposition system of claim 1 wherein the process conditions are chosen for depositing compound semiconductor materials.

7. The linear cluster deposition system of claim 1 wherein the process conditions are chosen for depositing elemental semiconductor materials.

8. The linear cluster deposition system of claim 1 wherein the plurality of reaction chambers is dimensioned to process a single substrate.

9. The linear cluster deposition system of claim 1 wherein each of the plurality of reaction chambers have substantially the same dimensions.

10. The linear cluster deposition system of claim 1 wherein the substrate transport vehicle comprises a robot.

11. The linear cluster deposition system of claim 10 wherein the robot moves along a rail positioned adjacent to the plurality of reaction chambers.

12. The linear cluster deposition system of claim 1 wherein the transport vehicle comprises a Venturi end-effector that transports substrates without physical contact.

13. The linear cluster deposition system of claim 1 wherein the transport vehicle comprises a fork-shaped end-effector that transports a substrate carrier into and output of the plurality of reaction chambers.

14. The linear cluster deposition system of claim 1 wherein the substrate transfer port comprises a door including a vacuum seal.

15. The linear cluster deposition system of claim 14 wherein the door is pneumatically controlled.

16. The linear cluster deposition system of claim 1 wherein the substrate transfer port comprises a gate valve.

17. The linear cluster deposition system of claim 1 further comprising a cleaning chamber positioned adjacent to at least some of the plurality of reaction chambers and positioned so that the substrate transport vehicle transports a substrate carrier from one of the plurality of reaction chambers to the cleaning chamber for cleaning.

18. The linear cluster deposition system of claim 17 wherein the cleaning chamber comprises a vacuum bake furnace.

19. The linear cluster deposition system of claim 17 further comprising a halide gas source having an output that is coupled to an input of the cleaning chamber, the halide gas source providing a halide gas environment for cleaning at least one of a substrate carrier and a substrate.

20. The linear cluster deposition system of claim 19 wherein the halide gas source comprises a chlorine gas source.

21. The linear cluster deposition system of claim 1 wherein the at least one process parameter comprises at least one of process gas flow rate into the process gas input ports, pressure inside the plurality of reaction chambers, and temperature inside the plurality of reaction chambers.

22. A linear cluster deposition system comprising:
a) a plurality of reaction chambers positioned in a linear horizontal arrangement, each of the plurality of reaction chambers having a process gas input port coupled to a mass flow controller, an exhaust gas output port, and a substrate transfer port;
b) at least two deposition monitors that monitor films grown in at least two of the plurality of reaction chambers;
c) a first and second reactant gas manifold each of the first and second reactant gas manifold having a plurality of process gas outputs, a respective one the plurality of process gas outputs of each of the first and second reactant gas manifold being coupled to a respective process gas input port of each of the plurality of reaction chambers;
d) an exhaust gas manifold having a plurality of exhaust gas inputs, a respective exhaust gas input being coupled to a respective exhaust gas output port of the plurality of reaction chambers;
e) a substrate transport vehicle that transports at least one of a substrate and a substrate carrier that supports at least one substrate into and out of the substrate transfer ports of each of the plurality of reaction chambers; and
f) a processor having at least two sensor inputs, a respective one of the at least two sensor inputs being electrically coupled to an output of a respective one of the at least two deposition monitors, and having at least two outputs, a respective one of the at least two outputs being coupled to a control input of a respective one of the mass flow controllers, the processor generating control signals at the at least two outputs that adjust a process gas flow rate of the respective mass flow controller to achieve substantially the same process conditions in at least two of the plurality of reaction chambers.

23. The linear cluster deposition system of claim 22 wherein the process conditions are chosen for organometallic vapor-phase epitaxy.

24. The linear cluster deposition system of claim 22 wherein the process conditions are chosen for halide vapor phase epitaxy.

25. The linear cluster deposition system of claim 22 wherein the process conditions are chosen for chemical vapor deposition.

26. The linear cluster deposition system of claim 22 wherein the process conditions are chosen for hydride vapor phase epitaxy.

27. The linear cluster deposition system of claim 22 wherein the process conditions are chosen for depositing compound semiconductor materials.

28. The linear cluster deposition system of claim 22 wherein the process conditions are chosen for depositing elemental semiconductor materials.

29. The linear cluster deposition system of claim 22 wherein each of the plurality of reaction chambers is dimensioned to process a single substrate.

30. The linear cluster deposition system of claim 22 wherein the deposition monitor monitors at least one of film growth rate and film thickness.

31. The linear cluster deposition system of claim 22 wherein the deposition monitor monitors at least one of film composition, film stress, film density, and optical transmission.

32. The linear cluster deposition system of claim 22 wherein the deposition monitor is positioned inside a respective one of the plurality of reaction chambers.

33. The linear cluster deposition system of claim 22 wherein at least one of the reaction chambers comprises an exhaust gas valve having a control input that is electrically connected to one of the at least two outputs of the processor, the processor generating a control signal that adjusts the position of the exhaust gas valve in order to achieve a desired chamber pressure in the at least one reaction chamber.

34. The linear cluster deposition system of claim 22 wherein the processor generates control signals that achieve substantially the same deposition conditions in all of the plurality of reaction chambers.

35. A method of simultaneous depositing material in a plurality of reaction chambers, the method comprising:
a) providing a plurality of reaction chambers positioned in a linear horizontal arrangement;
b) flowing reactant gas from at least two common reactant gas manifolds into each of the plurality of reaction chambers;
c) exhausting reactant gas and reaction products from the plurality of reaction chambers into a common exhaust gas manifold;
d) adjusting at least one processing parameter or reaction chamber parameter in at least one of the plurality of reaction chambers to achieve at least one film parameter that is substantially the same in at least two of the plurality of reaction chambers; and
e) transporting at least one of a substrate and a substrate carrier that supports at least one substrate into and out of each of the plurality of reaction chambers for simultaneous deposition.

36. The method of claim 35 wherein the process conditions are chosen for organometallic vapor-phase epitaxy.

37. The method of claim 35 wherein the process conditions are chosen for halide vapor phase epitaxy.

38. The method of claim 35 wherein the process conditions are chosen for chemical vapor deposition.

39. The method of claim 35 wherein the process conditions are chosen for hydride vapor phase epitaxy.

40. The method of claim 35 wherein the process conditions are chosen for depositing compound semiconductor materials.

41. The method of claim 35 wherein the process conditions are chosen for depositing elemental semiconductor materials.

42. The method of claim 35 wherein the transporting at least one of a substrate and a substrate carrier that supports at least one substrate into and out of each of the plurality of reaction chambers comprises transporting a single substrate into and out of each of the plurality of reaction chambers.

43. The method of claim 35 wherein the transporting at least one of a substrate and a substrate carrier that supports at least one substrate into and out of each of the plurality of reaction chambers comprises transporting a substrate without physical contact.

44. The method of claim 35 further comprising transporting at least one of a substrate and a substrate carrier that supports at least one substrate into a cleaning chamber for cleaning in at least one of a high temperature and a halide gas environment.

45. The method of claim 35 wherein the at least one film parameter is selected from the group comprising film thickness, film alloy composition, and film doping level.
